(19) United States
(12) Patent Application Publication
(10) Pub. No.: US 2013/0014813 A1
(43) Pub. Date: Jan. 17, 2013

(54) HIGH EFFICIENCY AND LOW COST GaInP/GaAs/Si TRIPLE JUNCTION BY EPITAXY LIFT-OFF AND MECHANICAL STACK

(71) Applicants: Weiming Wang, Ann Arbor, MI (US); Xin Zhu, Fremont, CA (US); Jun Yang, Cupertino, CA (US)

(72) Inventors: Weiming Wang, Ann Arbor, MI (US); Xin Zhu, Fremont, CA (US); Jun Yang, Cupertino, CA (US)

(21) Appl. No.: 13/347,712

(22) Filed: Jan. 11, 2012

Related U.S. Application Data
(60) Provisional application No. 61/431,480, filed on Jan. 11, 2011.

(51) Int. Cl. H01L 31/0336; H01L 31/18

(52) U.S. Cl. 136/255; 438/94; 257/E31.007

(57) ABSTRACT

The invention disclosed a method of fabricating GaInP/GaAs/Si triple junction solar cells by epitaxy lift-off and mechanical stack techniques. First, a GaInP(1.85 eV)/GaAs(1.42 eV) dual-junction cell is fabricated on a GaAs substrate, and a Si single junction is fabricated on a Si substrate. The Si single junction cell and the GaInP/GaAs dual-junction cell are joined together robustly by metal-metal bonding. A buffer layer, Gallium Phosphide (GaP) inserted between GaAs and Si can further optimize electrical, thermal and optical coupling. Furthermore, when a GaP layer is grown on a p-type Si substrate, a Si p-n junction as a fully functional solar cell is formed simultaneously, thereby reducing manufacturing cost. The technology can achieve GaInP/GaAs/Si triple junction solar cells of the conversion efficiency as high as 36% under a standard AM1.5 solar spectrum, with the optimal current 13.3 mA/cm² and the sum of open-circuit voltages 3.1V.

### CROSS-REFERENCE TO RELATED APPLICATIONS

This application claims the priority and benefit of U.S. Provisional Patent Application No. 61/431,480, entitled “High Efficiency and Low Cost GaInP/GaAs/Si Triple Junction by Epitaxy Lift-off and Mechanical Stack”, filed Jan. 11, 2011 by Weiming Wang, Xin Zhu and Jun Yang, the entire disclosure of which is hereby expressly incorporated by reference.

### BACKGROUND OF THE INVENTION

1. Field of the Disclosure

The present invention relates to general photovoltaic (PV) cells, and more particularly, to very high efficiency but low cost triple-junction solar cells, GaInP/GaAs/Si, by mechanically stacking a GaInP/GaAs dual-junction solar cell with a Si single junction solar cell, and thereafter by lifting off the GaInP/GaAs/Si triple-junction solar cell from the GaAs substrate.

2. Brief Description of Related Technology

The energy conversion efficiency of GaInP(1.85 eV)/GaAs(1.42 eV) dual junction solar cells can be as high as 30% under a standard AM1.5 solar spectrum W. However, only the photons with their energy larger than the band gap of GaAs (1.424 eV) can be captured in this structure. The amount of absorbable photons is only 45% of total photons in the solar spectrum. Therefore, it needs another low bandgap cell integrated with a GaInP/GaAs dual junction cell to harvest more photons. It is well known that GaInP(1.85 eV)/GaAs(1.42 eV)/Ge(0.67 eV) is the most well-developed triple junction structure because of nearly exact lattice match for all three of these materials. However, the bottom Ge cells made from Ge substrates with thickness more than 100 mm are really high cost. Also, the band gap of Ge (0.67 eV) is much smaller than the 1.0 eV which is the optimal bandgap for current match to a GaInP/GaAs dual-junction solar cell. And the Ge cell as the bottom sub-cell in the GaInP/GaAs/Ge triple junction only can contribute 0.2V open-circuit voltage. Therefore, the amount of efficiency increased by adding the Ge cell is very small. The recorded efficiency of this structure is only 31.5% under a standard AM1.5 solar spectrum [2]. On the other hand, the current match condition for the bottom cell can also be achieved by In_{0.3}Ga_{0.7}As alloy (bandgap equal to 1.0 eV) with 4% lattice mismatch with GaAs and GaInP. However, the defects in In_{0.3}Ga_{0.7}As caused by the strain of lattice mismatch also reduce its open-circuit voltage. In this invention, the processes of fabricating GaInP/GaAs/Si triple junction solar cell are disclosed, in which Si sub-cell can contribute the open-circuit voltage as high as 0.7V. Therefore, it can achieve the conversion efficiency about 36% under a standard AM1.5 spectrum, and more than 45% under concentration light. On the other hand, the manufacturing cost is significantly reduced by replacing Ge substrates by Si, and reusing the GaAs substrate.

The technology disclosed in U.S. Patent Pub. No. 20060021565A1 [3] used a direct semiconductor-semiconductor bonding process to join a GaInP/GaAs dual cell and a Si cell together. It required 1) ultra-clean surfaces for both GaAs and Si, 2) high temperature, and 3) high pressure for successful bonding. Furthermore, the difference of thermal expansion rate between GaAs and Si degraded the bonding strength.

In order to simplify the procedure and improve the reliability of GaAs/Si bonding, this invention disclosed a method to mechanically stack a GaInP/GaAs dual cell with Si a cell by using metal-metal bonding.

### SUMMARY OF THE INVENTION

In one embodiment, a method of fabricating GaInP/GaAs/Si triple junction solar cells by epitaxy lift-off and mechanical stack techniques as disclosed in this file. First, a GaInP(1.85 eV)/GaAs(1.42 eV) dual-junction cell is fabricated on a GaAs substrate, and a Si single junction is fabricated on a Si substrate. The Si single junction cell and the GaInP/GaAs dual-junction cell are bonded robustly by metal-metal welding. The welding process can be achieved by using mechanic pressure, or thermal, or cold-weld bonding, or their combinations. A buffer layer is disclosed to insert between to GaAs and Si to provide excellent electrical, thermal and optical joint. Furthermore, in the procedure of growing one of optimized buffer layer, GaP, the Si p-n junction as a fully functional solar cell is formed simultaneously, which further reduces the manufacturing cost for this technology. With the excellent thermal, electrical and optical joint, the optimal current-match as high as 13.3 mA/cm² can be achieved under standard AM1.5 spectrum while the sum of open-circuit voltages is 3.1V for GaInP/GaAs/Si triple junction. The total efficiency can be as high as 36% under a standard AM1.5 solar spectrum and more than 45% under concentration light. On the other hand, the manufacturing cost is significantly reduced by replacing Ge substrates by Si, and reusing the GaAs substrate.

### BRIEF DESCRIPTION OF THE DRAWING FIGURES

For a complete understanding of the disclosure, reference should be made to the following detailed description and accompanying drawing figures, in which like reference numerals identify like elements in the figures, and in which:

FIG. 1 is the schematic of a Si cell with a metal pattern

FIG. 2 is the schematic of a GaInP/GaAs cell on a GaAs substrate with a metal pattern.

FIG. 3 is the schematic of a GaInP/GaAs/Si triple junction solar cell after bonding.

FIG. 4 illustrates the device structure after the GaInP/GaAs dual junction is lifted off from the GaAs substrate.

FIG. 5 illustrates the device structure of GaInP/GaAs/Si triple junction solar cell with fabrication of the metal contacts (positive and negative) and Anti-Reflection Coating (ARC).

FIG. 6 illustrates the procedure to fabricate a Si cell by adding a gallium phosphide (GaP) as a buffer layer

FIG. 7 illustrates the GaInP/GaAs/Si triple junction solar cell with a buffer layer (GaP) between GaAs cell and Si cell.

While the disclosed methods and configuration are susceptible of embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DETAILED DESCRIPTION OF PREFERRED EMBODIMENTS

In the present disclosure, numerous specific details are provided such as examples of apparatus, process parameters, materials, process steps, and structures to provide a thorough understanding of embodiments of the invention. Persons of ordinary skills in art will recognize, however, that the invention can be practiced without one or more of specific details. In other words, well-known details are not shown or described to avoid obscuring aspects of the invention.

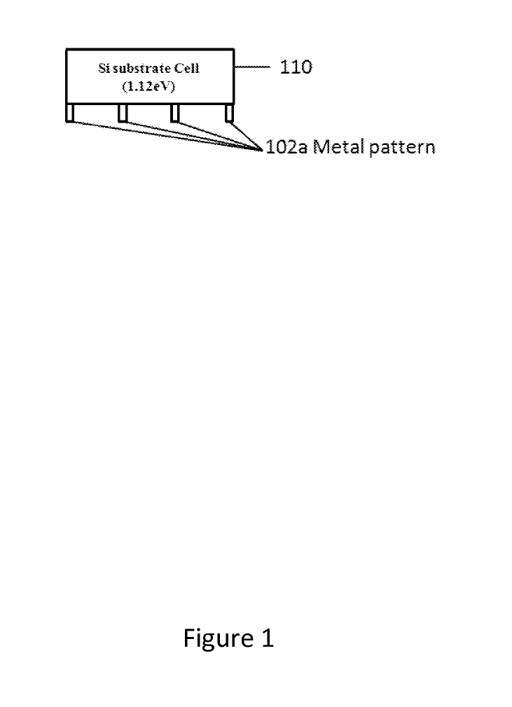

FIG. 1 illustrates a Si single junction solar cell 110 with a metal pattern 102a. The Si single junction solar cell 110 consists of a n-type emitter, a p-type absorber, and a metal contact for the p-type layer. The metal pattern 102a is fabricated by standard photolithography and lift-off processes with the total area less than 10% of the whole wafer. The metal for the pattern can be made from any one of the following metals, Au, Ag, Pt, Pd, In, Sn, Ti, Ni, Cr, Mo, Mn, Cu, Ge, or two or more of those formed alloy.

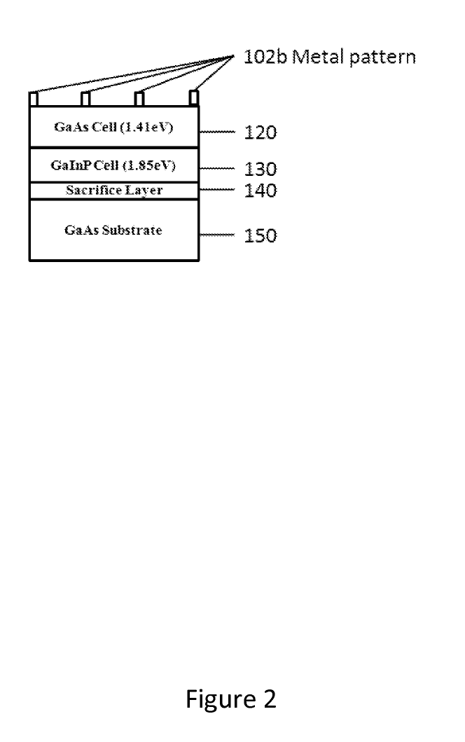

FIG. 2 shows a GaInP/GaAs dual-junction solar cell on a single crystal GaAs substrate 150 with a metal pattern 102b. The dual-junction cell consists of a GaAs sub-cell 120 and a GaInP sub-cell 130. The GaAs sub-cell 120 and the GaInP sub-cell 130 is connected by an internal tunnel PN junction. A sacrificial layer 140 with same or extremely close lattice constant with GaAs was firstly grown on the GaAs substrate 150. The thickness of the sacrifice layer 140 is typically from 10 nm to 100 nm. Besides the AlAs and AlGaAs alloy, the sacrificial layer 140 can also be ZnSe/MgS/ZnSe sandwich structure whose thickness are but not limited to be 10 nm, 20 nm, and 10 nm respectively. The metal pattern 102b is also achieved by photolithography and lift-off processes with the exactly same pattern of the metal pattern 102a in FIG. 1.

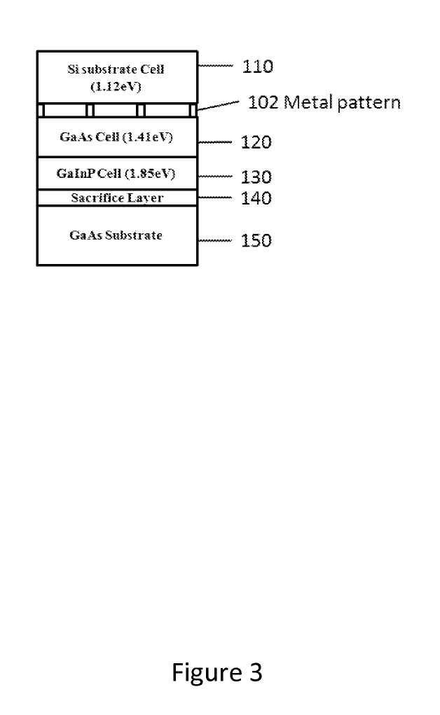

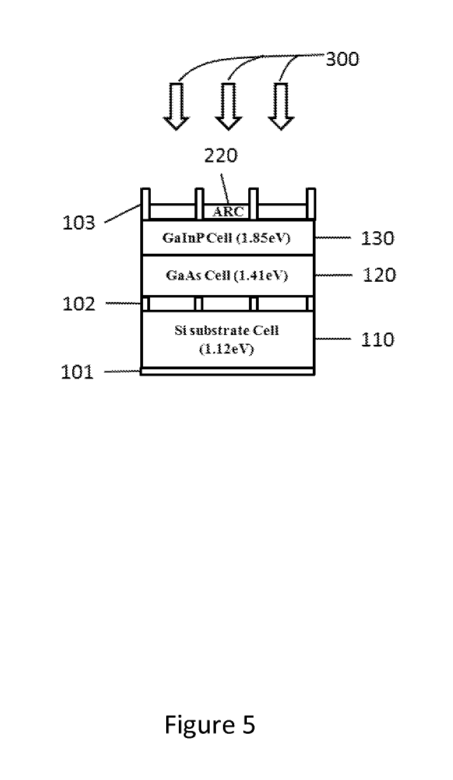

Once both metal pattern 102a and 102b are fabricated on the Si single junction solar cell and GaInP/GaAs dual-junction solar cell, they are aligned by a mask aligner, a bonding machine, or wafer stepper equipped with an infrared light source. The solid metal-metal joint can be achieved by mechanical, cold or thermal bonding. Thereafter, the stacked GaInP/GaAs/Si triple junction is illustrated in FIG. 3. Thereafter, the sacrificial layer with large etching selectivity of the layers in the GaInP sub-cell 130, the GaAs sub-cell 120 and Si single junction solar cells 110 is removed by a certain solution. For instance, a diluted HF solution can remove the AlAs or AlGaAs sacrificial layer without damaging any functional layer in the GaInP/GaAs/Si triple junction. Thereafter, the GaInP/GaAs/Si triple junction is separated from the substrate GaAs 150, which can be used to run another GaInP/GaAs dual-junction growth after a standard surface cleaning and polishing processes. Thereafter, as shown in FIG. 5, the bottom metal contact 101 and the top metal contact 103 are fabricated. The Anti-Reflection Coating (ARC) 220, typically with a double layer structure, such as SiO2/TiO2, AlOx/TiO2 or MgF/ZnSe is coated on the top surface of the GaInP/GaAs/Si triple junction.

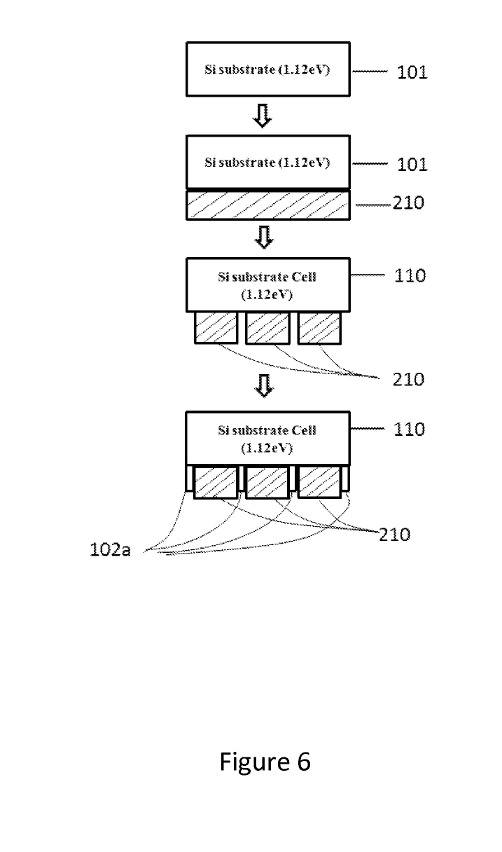

It should be pointed out the space gap between GaAs and Si in device shown in FIG. 5 may not avoid. The gap with distance more than 50 nm can result in significant optic loss because the light has to suffer two optical interfaces when it travels from GaAs to Si. In order to reduce the gap distance, a buffer 210 with optical refractive index very close to GaAs and Si is required to fill the gap. This invention is disclosing that Gallium Phosphide (GaP) is the ideal material to fill the gap between GaAs and Si with the following advantages: i) with optical refractive index greater than 3.0 at the range from 800 nm to 1200 nm infrared light, GaP can minimize the light reflection loss when the light travel from GaAs to Si; ii) with the bandgap of 2.3 eV, much larger than 1.424 eV, GaAs's bandgap, GaP is totally transparent for the infrared light from 800 nm to 1200 nm which is designed to be absorbed in the Si sub-cell 110; iii) GaP provides excellent thermal conductivity (1.1 Wcm⁻¹s⁻¹) to cool down the GaAs sub-cell 120, which is extremely important to operate the GaAs sub-cell properly under highly concentrated sunlight; iv) with almost the same lattice constant to Si, a GaP epitaxial layer in excellent crystal quality can be achieved on Si substrate by Metal Organic Chemical Vapor Deposition (MOCVD), Molecular Beam Epitaxy or other epitaxial approaches; v) the GaP epitaxial layer doped into high n-type conductivity (resistivity<0.005 Ω.cm) can provide additional electrical conduction channel besides the metal pattern 102 between the GaAs sub-cell (120) and the Si sub-cell (110); vi) the GaP epitaxial layer with high n-type conductivity and large band gap can service as a front-surface-field layer for the Si sub-cell to reduce the interface recombination rate; vii) the GaP epitaxy on Si provides a very simple method to make a Si sub-cell 110 as shown in FIG. 6.

The steps of making a Si sub-cell 110 are illustrated in FIG. 6. Starting from a p-type Si substrate 101, a certain thickness of GaP is epitaxially grown on the substrate under temperature more than 800° C. The GaP epitaxial layer 210 contributes the doping source, phosphor atoms, to diffuse into the Si substrate 101, and therefore convert p-type Si into n-type at the interface of GaP/Si. Finally a pn junction serving as a fully functional solar cell is formed on the Si substrate. Thereafter, a standard photolithography and etching processes are used to make a reserved pattern of the metal pattern 102a or 102b. Thereafter, a standard photolithography and lift-off processes are used to make the metal pattern 102a. In order to minimize the gap between the GaAs sub-cell 120 and the Si sub-cell 110, the thickness of GaP layer should be the same to or slightly less than the total thickness of metal pattern 102a and 102b.

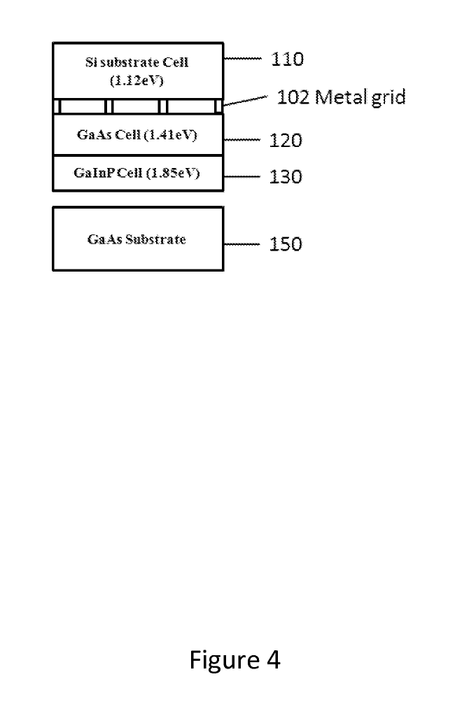

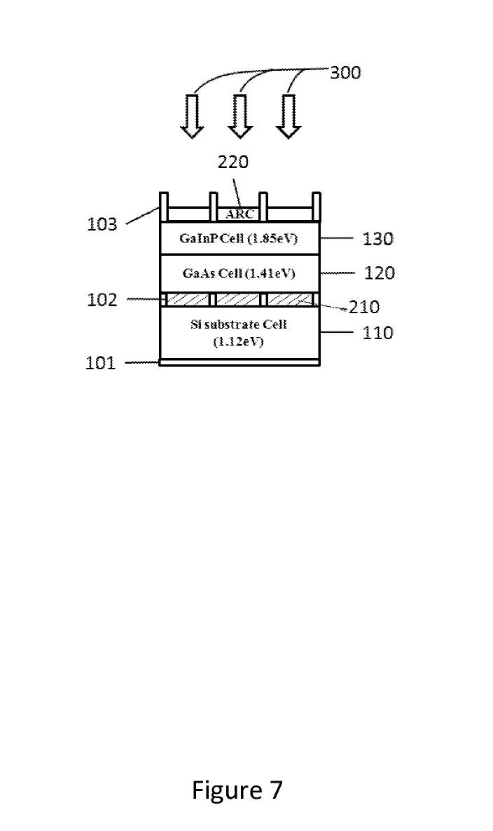

The Si sub-cell 110 with a GaP buffer layer 210 and the metal pattern 102a is then welded together with a GaInP/GaAs dual cell, as shown in FIG. 3, to form a GaInP/GaAs/Si triple junction, and then separate the triple junction cell from the GaAs substrate 150 by removing the sacrifice layer 140, as shown in FIG. 4. The final GaInP/GaAs/Si triple junction solar cell is illustrated in FIG. 7 with a buffer layer (GaP, but not limited to GaP) between GaAs/Si providing excellent thermal, electrical and optical joint.

In order to maximize the conversion efficiency of GaInP/GaAs/Si triple junction, the current match condition should be achieved by tuning the thickness of absorption layers in the GaInP sub-cell 130 and the GaAs sub-cell 120 or tuning the bandgap of the materials in absorption layers of GaAs sub-cell 120 and GaInP sub-cell 130. Under the AM1.5D spectrum, the maximum output current is 13.3 mA/cm², the open-circuit voltages can be as high as 1.4V, 1.0V, and 0.7V for GaInP sub-cell 130, GaAs sub-cell 120 and Si sub-cell 110 respectively. And a fully functional and high efficiency GaInP/GaAs/Si triple junction is therefore achieved by the technologies disclosed in this invention.

### REFERENCES

[1] Tattsuya Takomoto, Eiji Ikeda, Hiroshi Kurita and Masamichi Ohmori, Appl. Phys. Letts., 70, 381 (1997)
[2] R. R. King, D. C. Law, K. M. Edmondson, C. M. Fetzer, G. S. Kinsey, H. Yoon, R. A. Sherif, and N. H. Karam, 90, 183516 (2007)
[3] J. M. Zahler, H. A. Atwater, A. F. Morral, “GaInP/GaAs/Si Triple Junction solar cell enabled by wafer bonding and layer transfer” US Patent 20060021565A1

What is claimed:

1. A multi-junction photovoltaic (PV) solar cell comprised of:
a Si sub cell has a certain thickness of metal with the pattern as shown in FIG. 1;
a double-junction cell comprises a GaAs sub-cell and GaInP sub cell, wherein the GaAs sub-cell has a certain thickness of metal with the pattern as shown in FIG. 2, which can be partially overlapped with the metal pattern shown in FIG. 1;
an electrically conductive layer is formed with the adhesion of the above-mentioned two metal patterns using a mechanic, or thermal, or cold-weld bonding process, or their combinations, wherein the formed bonding layer has good electrical conductivity between the Si sub-cell and GaAs sub-cell.

2. The multi-junction photovoltaic (PV) solar cell of claim 1, wherein the material used in the metal patterns shown in FIGS. 1 and 2 include Al, Cu, Ni, Ti, Ge, Au, Ag, Zn, Pd, In, Sn, Pt, Cr, Mo, Mg, Mn, and two or more of those formed alloy.

3. A process for fabricating a multi-junction photovoltaic (PV) solar cell of claim 1 includes:
the fabrication of a double-junction cell comprising a GaAs sub-cell and GaInP sub cell;
the fabrication of a Si sub-cell;
the formation of a metal layer on Si sub-sell with the pattern shown as FIG. 1;
the formation of a metal layer on GaAs sub-cell with the pattern shown as FIG. 2, which can be partially overlapped with the metal pattern shown in FIG. 1;
a mechanic, or thermal, or cold-weld bonding process or their combinations, wherein an electrically conductive layer between the Si sub-cell and GaAs sub-cell is formed with the adhesion of the above two metal patterns under alignment.

4. By the use of the fabrication process of claim 3, the formation of a double-junction cell comprising a GaAs sub-cell and GaInP sub-cell composed of
a so-called sacrifice layer formed on the GaAs substrate;
a GaInP sub-cell formed on the sacrifice layer;
a GaAs sub-cell formed on the GaInP sub-cell; then
the removal of the sacrifice layer using etching process.

5. The sacrifice layer of claim 4 comprises a thin single layer of material or multiple layers of various materials, wherein those materials have significant higher etching rate in certain wet or dry etching process in contrast to PV cell materials such as GaAs and GaInP.

6. In addition to the common use of Al(Ga)As, the sacrifice layer of claims 4 and 5 can use ZnSe/MgS/ZnSe with sandwich structure.

7. The removal of the sacrifice layer of claims 4, 5, and 6 is the step after the mechanic, or thermal, or cold-welding bonding process, or their combinations.

8. The alignment required for the patterns (partially) overlap with each other is fulfilled using a microscope or exemplifier system installed with an infrared aligner, bonder or stepper.

9. A heterostructure multi-junction photovoltaic solar cell comprised of
a sub-cell has a certain thickness of metal with the pattern as shown in FIG. 1;
another sub cell has a certain thickness of metal with the pattern as shown in FIG. 2, which can be partially overlapped with the metal pattern shown in FIG. 1;
These two sub-cells have different bandgap, respectively corresponding to different wavelength range of solar spectra.
an electrically conductive layer is formed with the adhesion of the above two metal patterns using a mechanic, or thermal, or cold-weld bonding process, or their combinations, wherein the bonding layer is good electrically conduct layer between these two sub-cells.

10. The two-cells configuration and their adhesion in claim 9 can be further extended to three, four, and even more sub-cells by the use the fabrication approach in claims 3 and 9.

11. The multi-junction photovoltaic solar cells in claims 1, 3, and 9 have an appropriate material between sub-cells with the refractive index matching with or close to the PV cell materials, which could further minimize the light trapping/absorption.

12. Gallium Phosphide (GaP) is one of appropriate materials in claim 11 for the GaAs/GaInP cells, wherein
GaP can be deposited on either a Si sub-cell or a GaAs sub-cell by using MOCVD or MBE or other Epitaxial approaches providing excellent optical, electrical and thermal joint between GaAs and Si.

13. A fabrication approach of Si sub cell in claim 12, wherein,
GaP has lattice constant very close to Si, which can minimize the interface dislocation density and improve cell quality;
a GaP thin layer with a certain thickness (hundreds of nanometers) is deposited on a p-type Si substrate at the temperature greater than 800° C., the phosphor atoms in the GaP layer are preferable to diffusion into the Si substrate and form n-type layer in Si substrate. Consequently, the Si substrate with the p-n junction becomes a Si solar cell.

14. The optimal current match condition in the GaInP/GaAs/Si triple junction in claim 1 can be achieved, wherein, by
slightly tuning the thickness of absorption layer in GaInP sub-cell and GaAs sub-cell;
slightly tuning the bandgap of absorption layer in GaInP sub-cell and GaAs sub-cell with adding Al atoms.
